(19) United States
(12) Patent Application Publication
(10) Pub. No.: US 2019/0006530 A1
(43) Pub. Date: Jan. 3, 2019

(54) VARIABLE CAPACITOR LINEARITY IMPROVEMENT THROUGH DOPING ENGINEERING

(71) Applicant: QUALCOMM Incorporated, San Diego, CA (US)

(72) Inventors: Fabio Alessio MARINO, San Marcos, CA (US); Paolo MENEGOLI, San Jose, CA (US); Narasimhulu KANIKE, San Diego, CA (US); Qingqing LIANG, San Diego, CA (US); Francesco CAROBOLANTE, San Diego, CA (US)

(21) Appl. No.: 15/637,924

(22) Filed: Jun. 29, 2017

(51) Int. Cl. H01L 29/93; H01L 29/94; H01L 27/08; H01L 29/66

(52) U.S. Cl. CPC H01L 29/93; H01L 29/94; H01L 29/66189; H01L 29/66181; H01L 27/0805

(57) ABSTRACT

Certain aspects of the present disclosure provide a variable capacitor. The variable capacitor generally includes a semiconductor region, a dielectric layer disposed adjacent to the semiconductor region, and a first non-insulative region disposed above the dielectric layer, and a second non-insulative region disposed adjacent to the semiconductor region. In certain aspects, a doping concentration of the semiconductor region changes as a function of a distance across the semiconductor region from the dielectric layer or the second non-insulative region.

### TECHNICAL FIELD

Certain aspects of the present disclosure generally relate to electronic circuits and, more particularly, to a variable semiconductor capacitor.

### BACKGROUND

Semiconductor capacitors are fundamental components for integrated circuits. A variable capacitor is a capacitor whose capacitance may be intentionally and repeatedly changed under the influence of a bias voltage. A variable capacitor, which may be referred to as a varactor, is often used in inductor-capacitor (LC) circuits to set the resonance frequency of an oscillator, or as a variable reactance, e.g., for impedance matching in antenna tuners.

A voltage-controlled oscillator (VCO) is an example circuit that may use a varactor in which the thickness of a depletion region formed in a p-n junction diode is varied by changing a bias voltage to alter the junction capacitance. Any junction diode exhibits this effect (including p-n junctions in transistors), but devices used as variable capacitance diodes are designed with a large junction area and a doping profile specifically chosen to improve the device performance, such as quality factor and tuning range.

### SUMMARY

Certain aspects of the present disclosure generally include a variable capacitor. The variable capacitor generally includes a semiconductor region, a dielectric layer disposed adjacent to the semiconductor region, a first non-insulative region disposed above the dielectric layer, and a second non-insulative region disposed adjacent to the semiconductor region. In certain aspects, a doping concentration of the semiconductor region changes as a function of a distance across the semiconductor region from the dielectric layer or the second non-insulative region.

Certain aspects of the present disclosure generally include a method for fabricating a variable capacitor. The method generally includes forming a semiconductor region, forming a dielectric layer disposed adjacent to the semiconductor region, forming a first non-insulative region disposed above the dielectric layer, and forming a second non-insulative region disposed adjacent to the semiconductor region, where the semiconductor region is formed such that a doping concentration of the semiconductor region changes as a function of a distance across the semiconductor region from the dielectric layer or the second non-insulative region.

Certain aspects of the present disclosure generally include capacitive device. The capacitive device generally includes a first variable capacitor, where a first terminal of the first variable capacitor is coupled to a first terminal of the capacitive device, a second variable capacitor, where a first terminal of the second variable capacitor is coupled to a second terminal of the capacitive device, a first capacitor coupled between the second terminal of the capacitive device and a second terminal of the first variable capacitor, and a second capacitor coupled between the first terminal of the capacitive device and the second terminal of the second variable capacitor.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates an example semiconductor variable capacitor.

FIG. 2 illustrates an example differential semiconductor variable capacitor.

FIG. 3 is a graph illustrating example capacitance versus voltage (C-V) characteristics of a transcap device, in accordance with certain aspects of the present disclosure.

FIG. 4 is a graph illustrating the third order intermodulation product (IP3) of a transcap device, in accordance with certain aspects of the present disclosure.

FIG. 5 illustrates an example cross-coupled configuration for a capacitive devices, in accordance with certain aspects of the present disclosure.

FIG. 6 illustrates a capacitive device including transcap devices coupled in an anti-parallel configuration, in accordance with certain aspects of the present disclosure.

FIG. 7 is a graph illustrating the third order intermodulation distortion (IM3) of the capacitive device of FIG. 6, in accordance with certain aspects of the present disclosure.

FIG. 8 illustrates a capacitive device including transcap devices coupled in an anti-parallel configuration, in accordance with certain aspects of the present disclosure.

FIG. 9 is a graph illustrating the third order intermodulation distortion (IM3) of the capacitive device of FIG. 8, in accordance with certain aspects of the present disclosure.

FIG. 10 is a flow diagram of example operations for fabricating a variable capacitor, in accordance with certain aspects of the present disclosure.

### DETAILED DESCRIPTION

Aspects of the present disclosure are generally directed to a semiconductor capacitor. In certain aspects, a doping concentration of the semiconductor capacitor may be engineered to obtain a linear or exponential capacitance versus voltage (C-V) characteristic for the semiconductor capacitor.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

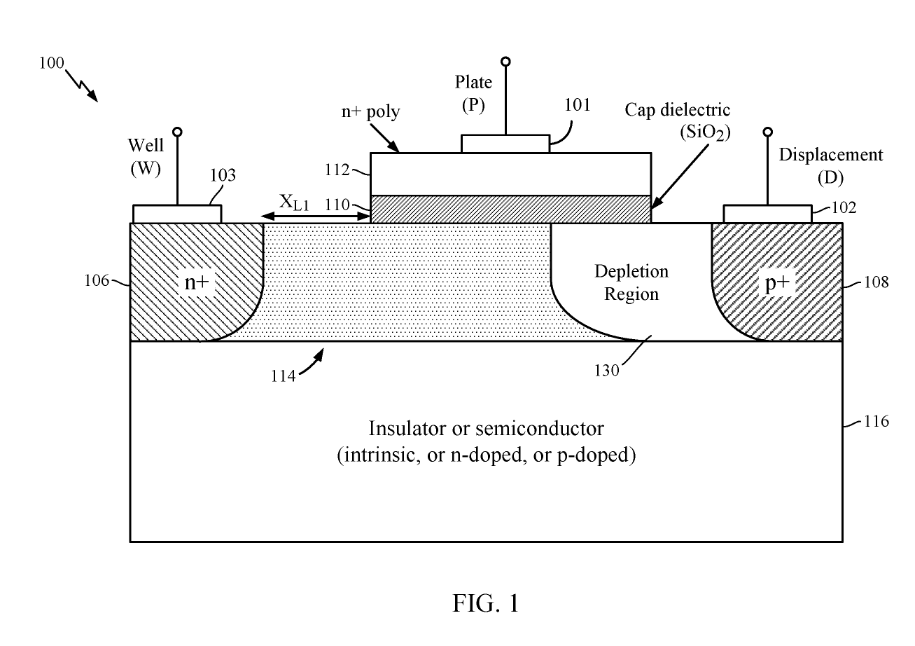

FIG. 1 illustrates an example structure of a transcap device 100. The transcap device 100 includes a non-insulative region 112 coupled to a plate (P) terminal 101, a non-insulative region 106 coupled to a well (W) terminal 103, and a non-insulative region 108 coupled to a displacement (D) terminal 102. Certain implementations of a transcap device use a plate oxide layer 110 disposed above a semiconductor region 114. The plate oxide layer 110 may isolate the W and P terminals, and thus, in effect act as a dielectric for the transcap device 100. The non-insulative region 106 (e.g., heavily n doped region) and the non-insulative region 108 (e.g., heavily p doped region) may be formed on two sides of the transcap device 100 in order to create p-n junctions. As used herein, a non-insulative region and a displacement region generally refer to regions that may be conductive or semiconductive.

In certain aspects, a bias voltage may be applied between the D terminal 102 and the W terminal 103 in order to modulate the capacitance between the P and W terminals. For example, by applying a bias voltage to the D terminal 102, a depletion region 130 may be formed between the p-n junction of the non-insulative region 108 and the semiconductor region 114. Based on the bias voltage, this depletion region 130 may widen under the plate oxide layer 110, reducing the area of the equivalent electrode formed by the semiconductor region 114, and with it, the effective capacitance area and capacitance value of the transcap device 100. Furthermore, the bias of the W and P terminals may be set as to avoid the formation of an inverted region underneath the oxide and operate the transcap device 100 in deep depletion mode. By varying the voltage of the W terminal with respect to the P and D terminals, both vertical and horizontal depletion regions may be used to modulate the capacitance between the W and P terminals.

The work-function of the non-insulative region 112 above the plate oxide layer 110 may be chosen to improve the device performance. For example, an n-doped poly-silicon material may be used (instead of p-doped), even if the semiconductor region 114 underneath the plate oxide layer 110 is doped with n-type impurities. In some aspects, a metallic material (also doped if desired) may be used for the non-insulative region 112 with an opportune work-function or a multi-layer stack of different metallic materials to obtain the desired work-function. In certain aspects, the non-insulative region 112 may be divided into two sub-regions, one n-doped and one p-doped, or a different metallic material may be used for each sub-region.

In some cases, the semiconductor region 114 may be disposed above an insulator or semiconductor region 116. The type of material for the semiconductor region 116 may be chosen in order to improve the transcap device 100 performance. For example, the semiconductor region 116 may be an insulator, a semi-insulator, or an intrinsic/near-intrinsic semiconductor in order to decrease the parasitic capacitances associated with the transcap device 100. In some cases, the semiconductor region 116 may be made of n-doped or p-doped semiconductor with an appropriate doping profile in order to increase the transcap device Q and/or the control on the depletion region 130 that may be formed between the non-insulative region 108 and the semiconductor region 114 when applying a bias voltage to the D terminal 102. The semiconductor region 116 may also be formed by multiple semiconductor layers or regions doped in different ways (n, p, or intrinsic). Furthermore, the semiconductor region 116 may include semiconductors, insulating layers, and/or substrates or may be formed above semiconductors, insulating layers, and/or substrates.

To better understand the working principle of the transcap device 100, it may be assumed that the D terminal 102 is biased with a negative voltage with respect to the W terminal 103. The width of the depletion region 130 in the semiconductor region 114 may be controlled by applying a control voltage to the D terminal 102 or to the W terminal 103. The capacitance between the W and P terminals may depend on the width of the depletion region 130 in the semiconductor region 114, and thus, may be controlled by applying the control voltage to the D terminal 102. Furthermore, the variation of the bias voltage applied to the D terminal 102 may not alter the direct-current (DC) voltage between the W and P terminals, allowing for improved control of the device characteristics.

In some cases, it may be preferable to have the non-insulative region 106 and/or non-insulative region 108 a distance away from the plate oxide layer 110 in order to reduce the parasitic capacitance associated with the non-insulative region 108 and improve the isolation of the non-insulative region 106 for high control voltages. For example, the non-insulative region 106 may be partially overlapped with the plate oxide layer 110, or the non-insulative region 106 may be formed at a distance from the edge of the plate oxide layer 110 to increase the device tuning range and linearity. In the latter case, the voltage-withstanding capability of the device is improved since a portion of a radio-frequency (RF) signal, that may be applied to the P and W terminals, drops between the oxide edge and the non-insulative region 106 instead of being applied entirely across the plate oxide layer 110. The non-insulative region 108 may be partially overlapped with the plate oxide layer 110, or the non-insulative region 108 may be spaced apart so as to reduce the parasitic capacitance between the P terminal and the D terminal 102.

In certain aspects, the semiconductor region 114 may be implemented with a p-well region to improve the breakdown voltage of the p-n junction between the non-insulative region 108 and the semiconductor region 114, decreasing, at the same time, the parasitic capacitance between the P terminal and the D terminal 102, as described in more detail herein. Similarly, the semiconductor region 114 may be implemented with an n-doped region between the non-insulative region 106 and semiconductor region 114 in order to regulate the doping concentration between the plate oxide layer 110 and the non-insulative region 106, as described in more detail herein. In certain aspects of the present disclosure, the semiconductor region 114 may be implemented with two or more regions having different doping concentrations and/or different doping types. A junction between the two or more regions may be disposed below the plate oxide layer 110 to improve the Q of the transcap device 100. In certain aspects, the doping concentration of the semiconductor region 114 may be engineered to obtain a linear or exponential capacitance versus voltage (C-V) characteristic for the transcap device 100, as will be described in more detail herein.

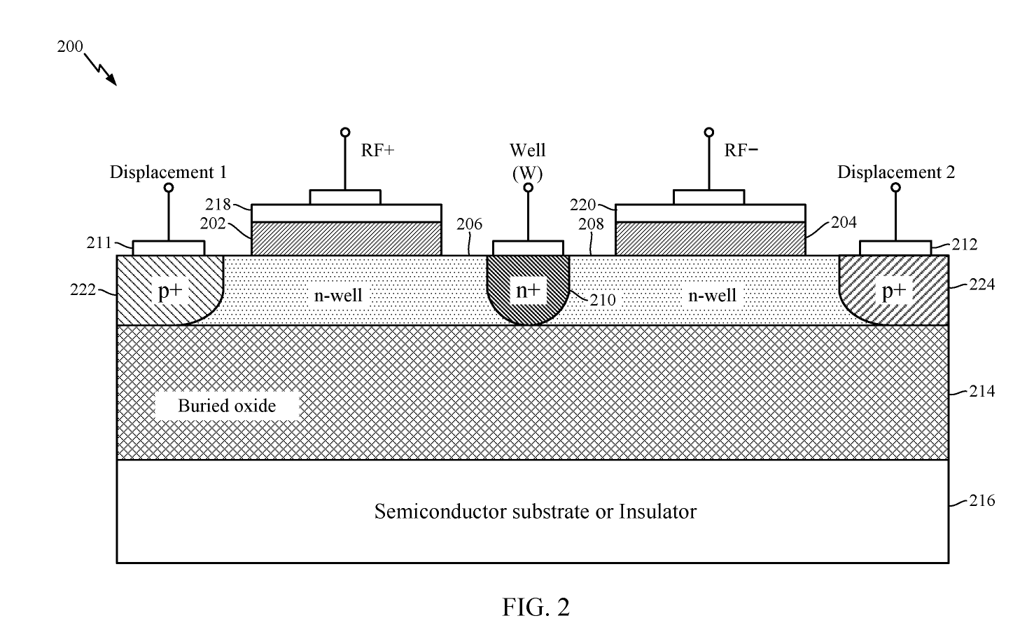

FIG. 2 illustrates an example differential transcap device 200. The differential transcap device 200 may be obtained by disposing two of the transcap devices 100 back-to-back. In this example, RF+ and RF− terminals (e.g., corresponding to the P terminal in FIG. 1) correspond to the positive and negative nodes of a differential RF port for a differential RF signal. The RF+ terminal may be coupled to a non-insulative region 218, and the RF− terminal may be coupled to a non-insulative region 220, each of the non-insulative regions 218 and 220 disposed above respective oxide layers 202 and 204. N-well regions 206 and 208 may be coupled to a W terminal via a non-insulative region 210 (e.g., n+), as illustrated. The differential transcap device 200 also includes D terminals 211 and 212 coupled to respective non-insulative regions 222 and 224. A bias voltage may be applied to the D terminals 211 and 212 (or to the W terminal with respect to the other terminals of the device) to adjust a depletion region of the n-well regions 206 and 208, respectively, thereby adjusting the capacitance between respective RF+ and RF− terminals and the W terminal. In some aspects, a buried oxide layer 214 may be positioned below the n-well regions 206 and 208 and above a semiconductor substrate or insulator 216, as illustrated. In certain aspects, the doping concentration of the n-well regions (e.g., semiconductor regions) may be engineered to obtain a linear or exponential capacitance versus voltage (C-V) characteristic for the differential transcap device 200, as will be described in more detail herein.

The capacitance density achievable with the transcap technology can be increased at the expense of device performance. For example, with reference to FIG. 2, the capacitance density may be increased by reducing the distance between the non-insulative regions 218 and 220 for the RF+ and RF− terminals. However, reducing the distance between the non-insulative regions 218 and 220 may increase the parasitic capacitance associated with the structure, lowering the tuning range of the differential transcap device 200.

The capacitor-voltage (C-V) characteristic of the transcap device 100 determines its performance parameters, such as tuning range (Cmax/Cmin), max control voltage for achieving the full tuning range, Q, and linearity of the transcap device. However, these figures of merit may depend on several process parameters, such as well doping, oxide thickness, n+/p+ proximity to the Plate terminal, and Plate length. In particular, the transcap device linearity can be improved, for example, by increasing the poly oxide thickness and/or by stacking multiple devices in series so as to decrease the voltage drop across each of them. However, these techniques may increase the area consumed by the transcap device, as well as degrade the device tuning range and/or quality factor due to increased parasitic components. Moreover, increasing the oxide thickness may involve process modification to fabricate the transcap device. Certain aspects of the present disclosure provide techniques for improving the linearity of a transcap device through the engineering of the doping profile in the semiconductor region of the transcap device without degrading the transcap device performance and/or increasing transcap device area.

Certain aspects of the present disclosure use results obtained through a Volterra analysis of a semiconductor variable capacitor fabricated using metal-oxide semiconductor (MOS) technology. The Volterra analysis shows that if a capacitance of the semiconductor variable capacitor varies exponentially with the bias voltage (or, more in particular, with the voltage across the semiconductor variable capacitor), it is possible to cancel the third-order intermodulation product (IM3) and therefore improve the device linearity. Certain aspects of the present disclosure provide techniques for engineering the doping profile of a semiconductor region of a transcap device (or any capacitor fabricated using MOS technology) to obtain an exponential (or linear) capacitance versus voltage (C-V) characteristic for the transcap device. For example, obtaining an exponential C-V characteristic serves to cancel the IM3 of the transcap device.

The relationship between the doping profile and the transcap device C-V characteristic may derived as follows:

$$C = \frac{dQ}{dV} , dQ = qN ( x ) dx , dx = d ( {ɛ}_{s} {C}^{- 1} ) = - {ɛ}_{s} {C}^{- 2} dC$$

$$dV = \frac{dQ}{C} = - \frac{qN ( x ) {ɛ}_{s} {C}^{- 2} dC}{C}$$

where C is the capacitance of the transcap device, N(x) is the doping concentration at a distance x from the silicon/oxide interface (e.g., from the plate oxide layer 110), εₛ is the semiconductor dielectric constant (e.g., dielectric constant of semiconductor region 114), V is the control voltage applied to the D terminal of the transcap device, and Q is the charge of the transcap device. Therefore, the relationship between the doping profile and the transcap device C-V characteristic can be represented by the following equation:

$$N ( x ) = - \frac{{C}^{3}}{q {ɛ}_{s}} {( \frac{dC}{dV} )}^{- 2} = {2 [ q {ɛ}_{s} \frac{d ( \frac{1}{{C}^{2}} )}{dV} ]}^{- 1}$$

where q is the elementary charge of an electron. The doping profile of the semiconductor region 114 to obtain an exponential C-V characteristic may be derived as follows:

$${C}_{tot} ( {V}_{R} ) = {( \frac{1}{{C}_{dep}} + \frac{1}{{C}_{ox}} )}^{- 1} = {a}_{1} exp ( {a}_{2} {V}_{R} ) ,$$

where Cₜₒₜ is the total capacitance of the transcap device, V_{R}=Vₛₜ+Vₒₓ+V_{FB}, Vₛᵢ is the voltage drop across the silicon charge distributions, Vₒₓ is the voltage drop across the oxide (e.g., the plate oxide layer 110), V_{FB} is the flat band voltage of the transcap device, a₁ and a₂ are coefficients of the exponential equation, C_{dep} is the depletion capacitance per unit area, and Cₒₓ is the dielectric (e.g., the plate oxide layer 110) capacitance per unit area.

Therefore

$${C}_{dep} = {( \frac{1}{{a}_{1} exp ( {a}_{2} {V}_{R} )} - \frac{1}{{C}_{ox}} )}^{- 1}$$

$$\begin{matrix}\frac{{dC}_{dep}}{{dV}_{si}} = [ {( \frac{1}{{a}_{1} exp ( {a}_{2} {V}_{R} )} - \frac{1}{{C}_{ox}} )}^{2} \times {a}_{2} \frac{1}{{a}_{1}} exp ( - {a}_{2} {V}_{R} ) \times \frac{{dV}_{R}}{{dV}_{si}} ] \\ = [ {a}_{2} {C}_{dep}^{2} \times ( \frac{1}{{C}_{dep}} + \frac{1}{{C}_{ox}} ) \times \frac{{dV}_{R}}{{dV}_{si}} ]\end{matrix}$$

$${V}_{si} = ( {V}_{R} - {V}_{FB} ) \times \frac{\frac{1}{{C}_{dep}}}{\frac{1}{{C}_{ox}} + \frac{1}{{C}_{dep}}}$$

$${V}_{R} = {V}_{si} \times {( \frac{\frac{1}{{C}_{dep}}}{\frac{1}{{C}_{ox}} + \frac{1}{{C}_{dep}}} )}^{- 1} + {V}_{FB}$$

$$\frac{{dV}_{R}}{{dV}_{si}} = {( \frac{\frac{1}{{C}_{dep}}}{\frac{1}{{C}_{ox}} + \frac{1}{{C}_{dep}}} )}^{- 1}$$

$$\begin{matrix}\frac{{dC}_{dep}}{{dV}_{si}} = [ {a}_{2} {C}_{dep}^{2} \times ( \frac{1}{{C}_{dep}} + \frac{1}{{C}_{ox}} ) \times {( \frac{\frac{1}{Cdep}}{\frac{1}{{C}_{ox}} + \frac{1}{{C}_{dep}}} )}^{- 1} ] \\ = {a}_{2} {{C}_{dep}^{3} ( \frac{1}{{C}_{dep}} + \frac{1}{{C}_{ox}} )}^{2}\end{matrix}$$

Based on the previously derived relationship between the doping profile and the transcap device C-V characteristic, the doping concentration of the transcap device may be derived as follows:

$$\begin{matrix}{N}_{D} ( x ) = {2 [ q {ɛ}_{s} \frac{d ( \frac{1}{{C}_{dep}^{2}} )}{{dV}_{si}} ]}^{- 1} \\ = - \frac{{C}_{dep}^{3}}{q {ɛ}_{s}} {( \frac{{dC}_{dep}}{{dV}_{si}} )}^{- 1} \\ = - \frac{1}{q {ɛ}_{s} {a}_{2}} \frac{1}{{( \frac{1}{{C}_{dep}} + \frac{1}{{C}_{ox}} )}^{2}}\end{matrix}$$

$$since {C}_{dep} = \frac{{ɛ}_{s}}{x} , then {N}_{D} ( x ) = - \frac{{ɛ}_{s}}{{qa}_{2}} \frac{1}{{( x + \frac{{ɛ}_{s}}{{ɛ}_{ox}} {x}_{ox} )}^{2}}$$

$${N}_{D 0} = {N}_{D} ( 0 ) = - \frac{{ɛ}_{ox}^{2}}{{qa}_{2} {ɛ}_{s} {x}_{ox}^{2}} ⇒ {a}_{2} = - \frac{{ɛ}_{ox}^{2}}{{qN}_{D 0} {ɛ}_{s} {x}_{ox}^{2}}$$

Therefore, the doping concentration profile to obtain an exponential C-V characteristic is as follows:

$${N}_{D} ( x ) = {N}_{D 0} \frac{{ɛ}_{s}^{2} {x}_{ox}^{2}}{{ɛ}_{ox}^{2}} \frac{1}{{( x + \frac{{ɛ}_{s}}{{ɛ}_{ox}} {x}_{ox} )}^{2}} = {N}_{D 0} \frac{1}{{( \frac{{ɛ}_{ox} x}{{ɛ}_{s} {x}_{ox}} + 1 )}^{2}}$$

wherein x is the distance across the semiconductor region 114 from the plate oxide layer 110, xₒₓ is a thickness of the dielectric layer, εₛ is the dielectric constant of the semiconductor region, εₒₓ is the dielectric constant of the dielectric layer, and N_{D0} is the doping concentration at x=0. As shown above, the doping concentration is highest at or near the silicon/oxide interface (e.g., from the plate oxide layer 110). The doping profile can be obtained by using a multi-step doping implantation process or through epitaxial process steps. While the epitaxial process is more expensive, it may allow for higher precision in the doping profile definition. The total capacitance as a function of V_{R} when the device is working in depletion mode may be derived as follows:

$${C}_{tot} ( {V}_{R} ) = {a}_{1} exp ( {a}_{2} {V}_{R} ) = {a}_{1} exp ( - \frac{{ɛ}_{ox}^{2}}{q {ɛ}_{s} {N}_{D 0} {x}_{ox}^{2}} {V}_{R} )$$

$$Since for {V}_{R} = {V}_{FB} , \\ {C}_{tot} ( {V}_{FB} ) = {C}_{FB} = {a}_{1} exp ( {a}_{2} {V}_{FB} ) ⇒ {a}_{1} = {C}_{FB} exp ( \frac{{ɛ}_{ox}^{2}}{q {ɛ}_{s} {N}_{D 0} {x}_{ox}^{2}} {V}_{FB} )$$

$$therefore , {C}_{tot} ( {V}_{R} ) = {C}_{FB} exp ( - \frac{{ɛ}_{ox}^{2}}{q {ɛ}_{s} {N}_{D 0} {x}_{ox}^{2}} ( {V}_{R} - {V}_{FB} ) )$$

where V_{FB} is the flat band voltage of the transcap device, and

$${C}_{FB} = \frac{1}{\frac{1}{{C}_{ox}} + \frac{{L}_{D}}{{ɛ}_{s}}} , with {L}_{D} = Debye Length ≅ \sqrt{\frac{{ɛ}_{s} {V}_{t}}{{qN}_{D} ( 0 )}}$$

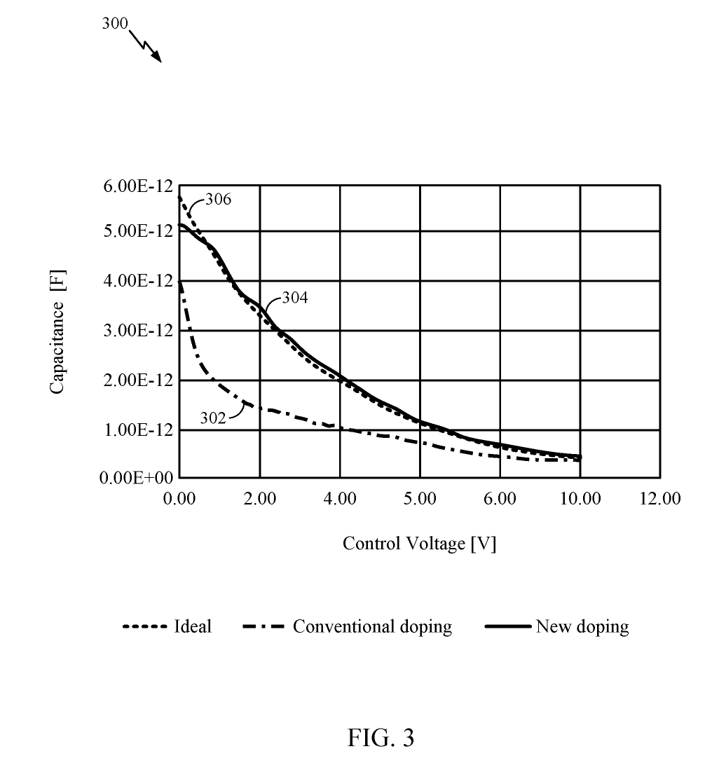

FIG. 3 is a graph 300 illustrating an example C-V characteristic of a transcap device, in accordance with certain aspects of the present disclosure. The line 302 illustrates the C-V characteristic of a conventional n-well profile transcap device and the line 304 illustrates the C-V characteristic of a transcap device having a doping profile concentration set to obtain an exponential C-V characteristic as described previously. As illustrated, the C-V characteristic shown by line 304 closely matches the ideal exponential C-V characteristic as shown by line 306.

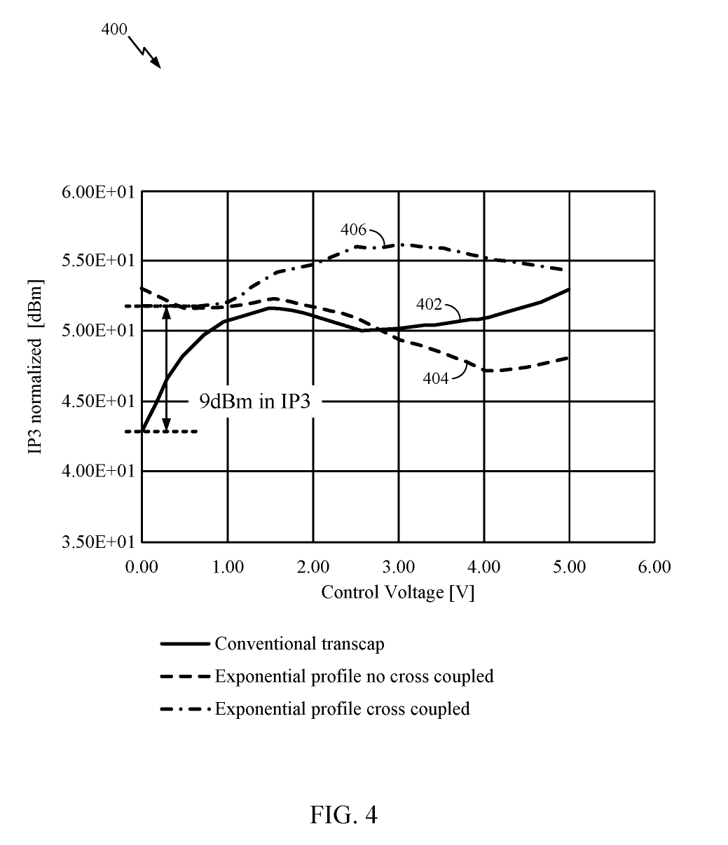

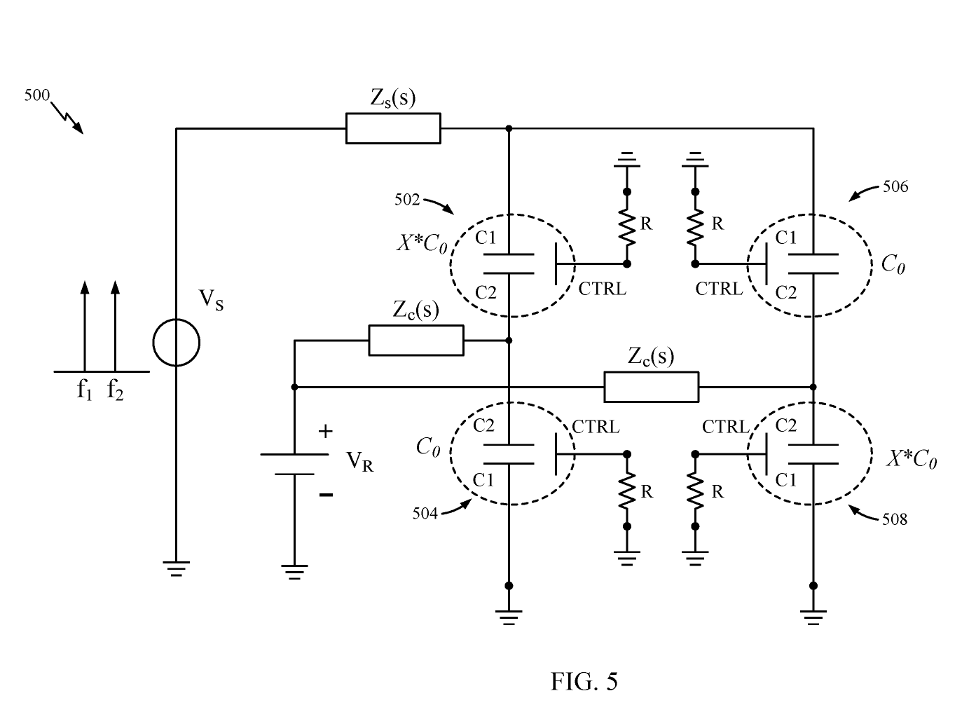

FIG. 4 is a graph 400 that illustrates a third order intermodulation product IP3 (normalized to the capacitance value) of a transcap device, in accordance with certain aspects of the present disclosure. The IP3 of the transcap device is shown as a function of a control bias for a conventional transcap device with a baseline n-well doping scheme as shown by line 402, and for a transcap device with a well doping profile set to obtain an exponential C-V characteristic as shown by line 404. At low control voltages, the transcap device employing the doping scheme of the present disclosure shows an IP3 improvement with respect to the conventional transcap device of up to 9 dBm. To improve the linearity at higher control voltages, a cross-coupled configuration may be used. For example, line 406 illustrates the IP3 for a capacitive device having cross-coupled transcap devices, each having a doping profile set to obtain an exponential C-V characteristic, as will be described in more detail with respect to FIG. 5.

FIG. 5 illustrates an example cross-coupled configuration for a capacitive device 500, in accordance with certain aspects of the present disclosure. As illustrated, a first differential transcap device is formed by transcap devices 502 and 504, and a second differential transcap device is formed by transcap devices 506 and 508. The first and second differential transcap devices are coupled in parallel. By cross-coupling the transcap devices as illustrated in FIG. 5, the linearity of the capacitive device 500 is improved as compared to a single transcap device. In certain aspects, the area of the transcap devices 502 and 508 may be different than the area of transcap devices 504 and 506. For example, C0 represents the area of a unit transcap device, and the ratio X of the area of the transcap devices of each branch may be selected to cancel the third order intermodulation distortion IM3. In certain aspects, the ratio X may be:

2±\sqrt{3}

to nullify the IM3 in the cross-coupled configuration illustrated in FIG. 5.

In certain aspects, a linear C-V characteristic may be obtained to improve the transcap device performance. The doping concentration profile of the semiconductor region 114 to obtain a linear C-V characteristic when the device is working in depletion mode may be derived as follows:

$${C}_{tot} ( {V}_{R} ) = {( \frac{1}{{C}_{dep}} + \frac{1}{{C}_{ox}} )}^{- 1} = a ( {V}_{R} - b )$$

where a and b are coefficients of the linear equation.

Therefore

$${C}_{dep} = {( \frac{1}{a {V}_{R}} - \frac{1}{{C}_{ox}} )}^{- 1}$$

$$\begin{matrix}\frac{{dC}_{dep}}{{dV}_{si}} = [ {( \frac{1}{{aV}_{R}} - \frac{1}{{C}_{ox}} )}^{- 2} \times \frac{a}{{{a}^{2} ( {V}_{R} - b )}^{2}} \times \frac{{dV}_{R}}{{dV}_{si}} ] \\ = [ {aC}_{dep}^{3} \times {( \frac{1}{{C}_{dep}} + \frac{1}{{C}_{ox}} )}^{3} ]\end{matrix}$$

Based on the previously derived relationship between the doping concentration profile and the transcap device C-V characteristic, the doping concentration may be derived as follows:

$$\begin{matrix}{N}_{D} ( x ) = {2 [ q {ɛ}_{s} \frac{d ( \frac{1}{{C}_{dep}^{2}} )}{{dV}_{si}} ]}^{- 1} \\ = - \frac{{C}_{dep}^{3}}{q {ɛ}_{s}} {( \frac{{dC}_{dep}}{{dV}_{si}} )}^{- 1} \\ = - \frac{1}{q {ɛ}_{s} a} \frac{1}{{( \frac{1}{{C}_{dep}} + \frac{1}{{C}_{ox}} )}^{3}}\end{matrix}$$

$$since {C}_{dep} = \frac{{ɛ}_{s}}{x} , then {N}_{D} ( x ) = - \frac{{ɛ}_{s}}{qa} \frac{1}{{( x + \frac{{ɛ}_{s}}{{ɛ}_{ox}} {x}_{ox} )}^{3}}$$

$${N}_{D 0} = {N}_{D} ( 0 ) = - \frac{1}{qa {ɛ}_{s}} \frac{{ɛ}_{ox}^{2}}{{x}_{ox}^{3}} ⇒ a = - \frac{{ɛ}_{ox}^{3}}{{qN}_{D 0} {ɛ}_{s} {x}_{ox}^{3}}$$

Therefore, the doping concentration profile to obtain a linear C-V characteristic is as follows:

$${N}_{D} ( x ) = {N}_{D 0} \frac{1}{{( \frac{{ɛ}_{ox} x}{{ɛ}_{s} {x}_{ox}} + 1 )}^{3}}$$

The total capacitance as a function of V_{R} may be derived as follows:

$${C}_{tot} ( {V}_{R} ) = a ( {V}_{R} - b ) = - \frac{{C}_{ox}^{3}}{{qN}_{D 0} {ɛ}_{s}} ( {V}_{R} - b )$$

Since for

$${V}_{R} = {V}_{FB} , {C}_{tot} ( {V}_{FB} ) = {C}_{FB} = a ( {V}_{FB} - b ) ⇒ b = - \frac{{C}_{FB}}{a} + {V}_{FB}$$

$$therefore , {C}_{tot} ( {V}_{R} ) = - \frac{{C}_{ox}^{3}}{{qN}_{D 0} {ɛ}_{s}} ( {V}_{R} - {V}_{FB} ) + {C}_{FB}$$

While the examples provided herein have described engineering the doping profile of a transcap device to facilitate understanding, the techniques described herein can be used to obtain any desired shape for the C-V characteristic of any variable capacitor manufactured using MOS technology. The techniques provided herein are especially advantageous for transcap devices, since transcap devices operate in a deep-depletion state without bringing the semiconductor/oxide interface in an inversion state, which would limit the depletion region extension obtainable under the oxide.

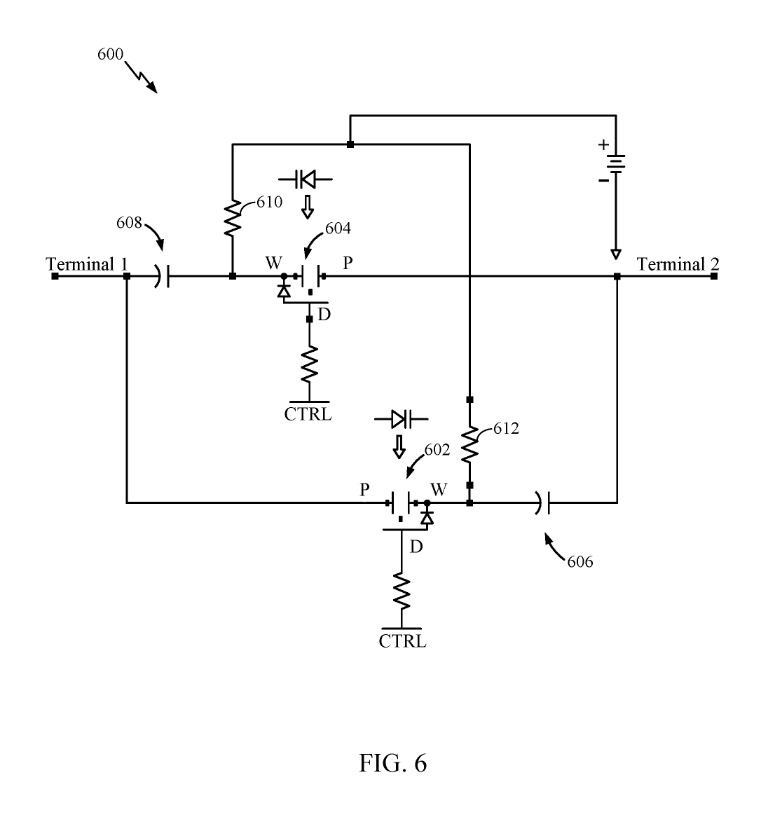

FIG. 6 illustrates a capacitive device 600 including transcap devices coupled in an anti-parallel configuration, in accordance with certain aspects of the present disclosure. As illustrated, the plate terminals of the transcap devices 602 and 604 are coupled to the first and second terminals of the capacitive device 600, respectively. The well terminals of the transcap devices 604 and 602 are coupled to the first and second terminals of the capacitive device 600, respectively, each through a capacitor 606 or 608. The capacitors 606 and 608 act as alternating current (AC) decoupling capacitors, allowing the W terminals of the transcap devices 602 and 604 to be biased. For example, the W terminals of the transcap devices 602 and 604 may be coupled to a voltage rail through resistive elements 610 and 612. By coupling the transcap devices 602 and 604 in an anti-parallel configuration, the linearity of the capacitive device 600 is improved as compared to a single transcap device. In certain aspects, one or more of the transcap devices 602 and 604 may be replaced by varactors, as illustrated. In certain aspects, the anode and cathode terminals of the varactors may be reversed with respect to what is shown in FIG. 6.

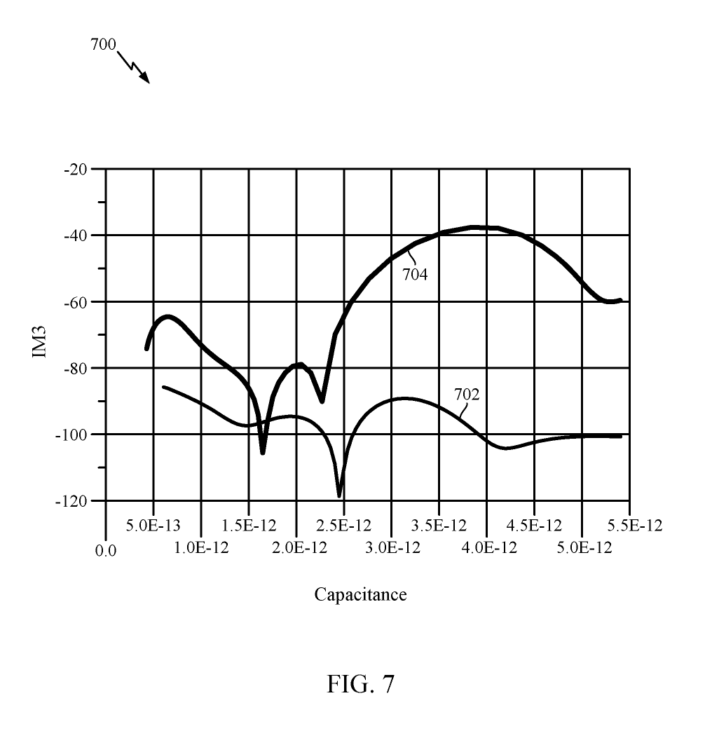

FIG. 7 is a graph 700 illustrating the IM3 of the capacitive device 600 normalized with respect to the voltage across the capacitance, in accordance with certain aspects of the present disclosure. The line 702 illustrates the IM3 of the capacitive device 600 versus the IM3 of a single transcap device represented by line 704. As illustrated, the IM3 of the capacitive device 600, including multiple transcap devices in an anti-parallel configuration, may be improved by about 50 dBs as compared to a single transcap device.

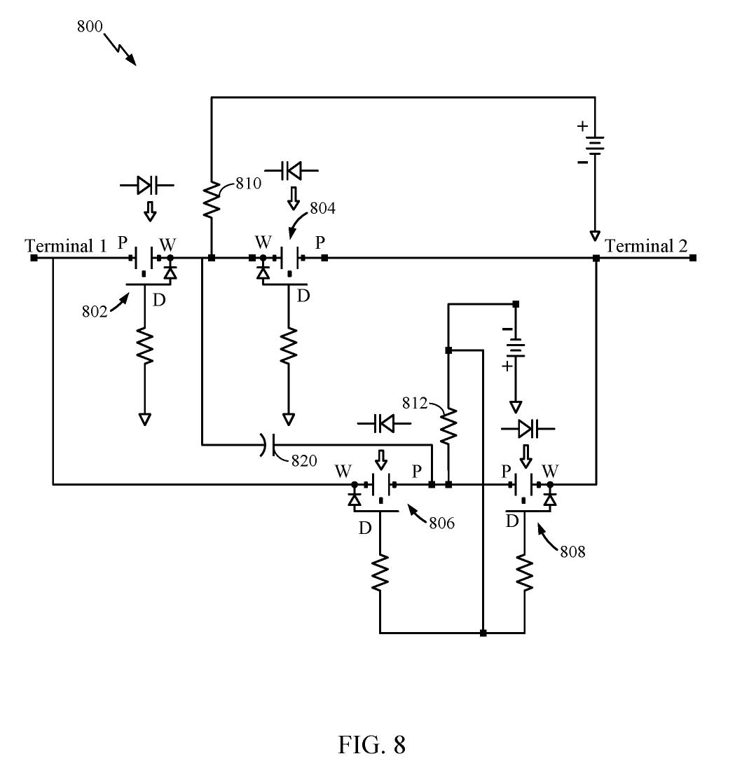

FIG. 8 illustrates a capacitive device 800 including transcap devices coupled in an anti-parallel configuration, in accordance with certain aspects of the present disclosure. The P terminals of the transcap devices 802 and 804 are coupled to the first and second terminals of the capacitive device 800, respectively. The W terminals of the transcap devices 806 and 808 are coupled to the first and second terminals of the capacitive device 800, respectively. The W terminals of the transcap devices 802 and 804 may be coupled to a voltage rail through a resistive device 810 to bias the W terminals of the transcap devices 802 and 804. Moreover, the P terminals of the transcap devices 806 and 808 may be coupled to a voltage rail through a resistive device 812 to bias the P terminals of the transcap devices 806 and 808. In this case, an AC decoupling capacitor 820 may be coupled between the W terminal of the transcap device 802 and the P terminal of the transcap device 806, as illustrated. In certain aspects, one or more of the transcap devices 802, 804, 806 and 808 may be replaced by varactors, as illustrated. The anode and cathode terminals of the varactors may be reversed with respect to what is shown in FIG. 8.

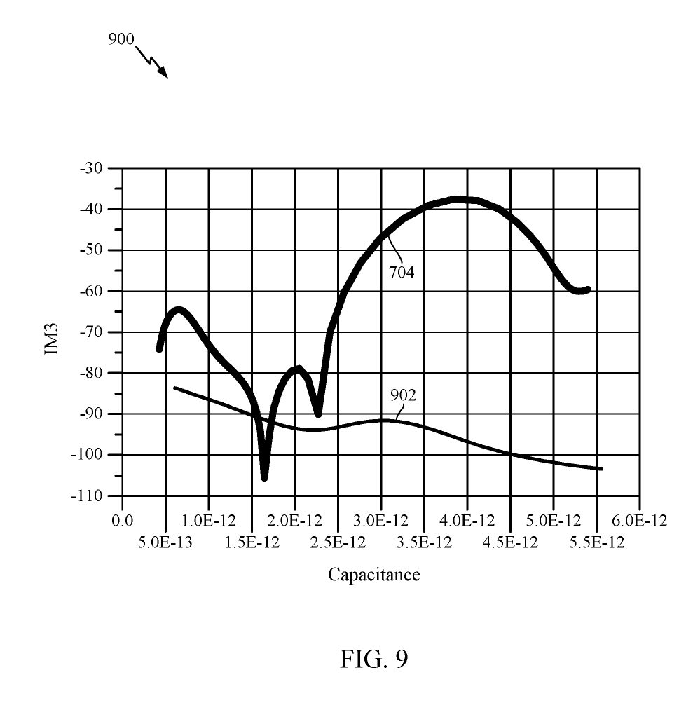

FIG. 9 is a graph 900 illustrating the IM3 of the capacitive device 800, in accordance with certain aspects of the present disclosure. The line 902 illustrates the IM3 of the capacitive device 800 versus the IM3 of a single transcap device as represented by line 704. As illustrated by graph 900, the configuration shown of the capacitive device 800 improves the IM3 as compared to a single transcap device.

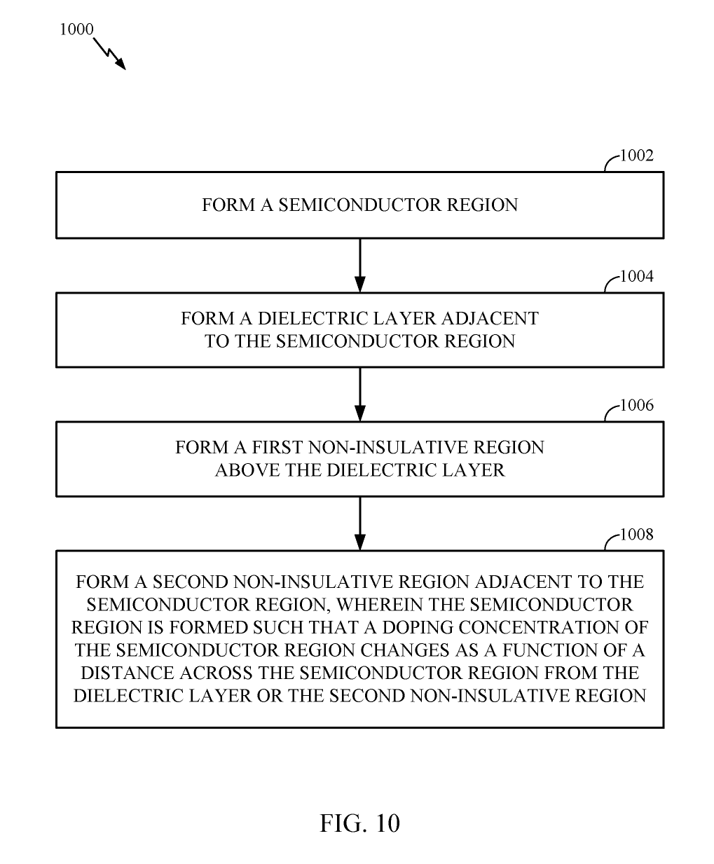

FIG. 10 is a flow diagram of example operations 1000 for fabricating a variable capacitor, in accordance with certain aspects of the present disclosure. The operations 1000 may be performed, for example, by a semiconductor-processing chamber.

Operations 1000 may begin at block 1002 by forming a semiconductor region (e.g., semiconductor region 114), and at block 1004, forming a dielectric layer (e.g., plate oxide layer 110) adjacent to the semiconductor region. At block 1006, a first non-insulative region (e.g., non-insulative region 112) is formed above the dielectric layer, at block 1008, a second non-insulative region (e.g., non-insulative region 106) is formed adjacent to the semiconductor region. In certain aspects, the semiconductor region is formed such that a doping concentration of the semiconductor region changes as a function of a distance across the semiconductor region from the dielectric layer or the second non-insulative region (e.g., to obtain a linear or exponential C-V characteristic, as described in more detail herein). The formation of the semiconductor region may involve a multi-step doping implantation process or through epitaxial process steps. As used herein, adjacent may refer to adjoining, contiguous, or near within the context of a variable capacitor, as would be understood by a person of ordinary skill in the art.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

1. A variable capacitor, comprising:
a substrate;
a semiconductor region above the substrate;
a dielectric layer disposed above the semiconductor region;
a first non-insulative region disposed above the dielectric layer; and
a second non-insulative region disposed adjacent to the semiconductor region, wherein a doping concentration of the semiconductor region changes as a function of a distance across the semiconductor region from the dielectric layer towards the substrate.

2. The variable capacitor of claim 1, wherein the doping concentration changes based on an equation:
$${N}_{D 0} \frac{1}{{( \frac{{ɛ}_{ox} x}{{ɛ}_{s} {x}_{ox}} + 1 )}^{2}}$$
wherein x is the distance across the semiconductor region from the dielectric layer, xₒₓ is a thickness of the dielectric layer, εₛ is the dielectric constant of the semiconductor region, εₒₓ is the dielectric constant of the dielectric layer, and N_{D0} is the doping concentration at x=0.

3. The variable capacitor of claim 2, wherein the doping concentration is set based on the equation to obtain an exponential capacitance versus voltage (C-V) characteristic for the variable capacitor.

4. The variable capacitor of claim 1, wherein the doping concentration changes based on an equation:
$${N}_{D 0} \frac{1}{{( \frac{{ɛ}_{ox} x}{{ɛ}_{s} {x}_{ox}} + 1 )}^{3}}$$
wherein x is the distance across the semiconductor region from the dielectric layer, xₒₓ is a thickness of the dielectric layer, εₛ is the dielectric constant of the semiconductor region, εₒₓ is the dielectric constant of the dielectric layer, and N_{D0} is the doping concentration at x=0.

5. The variable capacitor of claim 4, wherein the doping concentration is set based on the equation to obtain a linear capacitance versus voltage (C-V) characteristic for the variable capacitor, wherein the slope of the C-V characteristic is not zero.

6. The variable capacitor of claim 1, further comprising:
a third non-insulative region disposed adjacent to the semiconductor region such that a capacitance between the first non-insulative region and the second non-insulative region is configured to be adjusted by varying a control voltage applied to the third non-insulative region with respect to the first non-insulative region or the second non-insulative region.

7. The variable capacitor of claim 6, wherein:
the second non-insulative region has a positive doping type and the third non-insulative region has a negative doping type; or
the second non-insulative region has a negative doping type and the third non-insulative region has a positive doping type.

8. A method for fabricating a variable capacitor, comprising:
forming a semiconductor region above a substrate;
forming a dielectric layer above the semiconductor region;
forming a first non-insulative region above the dielectric layer; and
forming a second non-insulative region adjacent to the semiconductor region, wherein the semiconductor region is formed such that a doping concentration of the semiconductor region changes as a function of a distance across the semiconductor region from the dielectric layer towards the substrate.

9-22. (canceled)
